(19) United States
(12) Patent Application Publication
(10) Pub. No.: US 2005/0098869 A1
(43) Pub. Date: May 12, 2005

(54) Semiconductor device and method of manufacturing the same, circuit board, and electronic instrument

(75) Inventor: Masakuni Shiozawa, Sakata-shi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 10/951,783

(22) Filed: Sep. 29, 2004

(30) Foreign Application Priority Data
Sep. 30, 2003 (JP) 2003-339467

(51) Int. Cl. H01L 21/48; H01L 23/02

(52) U.S. Cl. 257/686; 438/109; 257/690; 257/692

(57) ABSTRACT

A first semiconductor ship is mounted on a first surface of an interposer in such a manner that a first electrode overlaps with a penetrating-hole, and a second semiconductor chip is stacked on the first semiconductor chip. A first wire is disposed on a second surface side and bonded to the first electrode and a second wiring pattern. A second wire is disposed on the first surface side and bonded to a second electrode and a first wiring pattern. A sealing section includes a first portion on the first surface, a second portion on the second surface, and a third portion linking the first and second portions through the penetrating-hole.

Japanese Patent Application No. 2003-339467, filed on Sep. 30, 2003, is hereby incorporated by reference in its entirety.

### BACKGROUND OF THE INVENTION

The present invention relates to a semiconductor device and a method of manufacturing the same, a circuit board, and also an electronic instrument.

During the manufacture of a semiconductor device, wire bonding is known as a highly reliable method of electrical connection. In a stacked type of semiconductor device wherein wire bonding is used, if the stacked semiconductor chips are of the same size (or if the upper semiconductor chip is larger), a spacer is interposed between the upper and lower semiconductor chips, which increases the thickness of the package. A technique is known of using wire bonding in a configuration in which a semiconductor circuit is bonded face-down on an interposer (see Japanese Patent Laid-Open No. 2000-138317). In this configuration, when another semiconductor chip is bonded face-up on the rear surface of the first semiconductor chip and also wire bonding is used, each of the semiconductor chips is individually sealed so it is possible that each sealing section could peel away.

### BRIEF SUMMARY OF THE INVENTION

A semiconductor device according to one aspect of the present invention includes:
an interposer having a first wiring pattern formed on a first surface of the interposer, a second wiring pattern formed on a second surface of the interposer, and a penetrating-hole formed in the interposer;
a first semiconductor chip having a first electrode and being mounted on the first surface of the interposer in such a manner that the first electrode overlaps with the penetrating-hole;
a second semiconductor chip having a second electrode and being stacked on the first semiconductor chip with the second electrode facing away from the first semiconductor chip;
a first wire disposed on a side of the second surface and being bonded to the first electrode and the second wiring pattern;
a second wire disposed on a side of the first surface and being bonded to the second electrode and the first wiring pattern; and
a sealing section which includes a first portion provided on the first surface of the interposer, a second portion provided on the second surface of the interposer, and a third portion provided through the penetrating-hole and linking the first and second portions, seals the first and second semiconductor chips, seals the first and second wires, and seals the bonding portions of the first and second wires with the first and second wiring patterns.

A circuit board according to another aspect of the present invention has the above semiconductor device mounted thereon.

An electronic instrument according to a further aspect of the present invention has the above semiconductor device.

A method of manufacturing a semiconductor device according a still further aspect of the present invention includes:
(a) mounting a first semiconductor chip on an interposer, the first semiconductor chip having a first electrode, and the interposer having a first wiring pattern formed on a first surface of the interposer, a second wiring pattern formed on a second surface of the interposer, and a penetrating-hole formed in the interposer, in such a manner that the first electrode overlaps with the penetrating-hole;
(b) stacking a second semiconductor chip having a second electrode on the first semiconductor chip, with the second electrode facing away from the first semiconductor chip;
(c) bonding a first wire to the first electrode and the second wiring pattern on a side of the second surface;
(d) bonding a second wire to the second electrode and the first wiring pattern on a side of the first surface; and
(e) by using a transfer molding method, sealing the first and second semiconductor chips, sealing the first and second wires, and sealing the bonding portions of the first and second wires with the first and second wiring patterns,
wherein in the step (e), resin flows through the penetrating-hole from one of the first and second surfaces of the interposer to the other, to form a sealing section which is formed integrally of a first portion on the first surface, a second portion on the second surface, and a third portion linking the first and second portions through the penetrating-hole.

### BRIEF DESCRIPTION OF THE SEVERAL VIEWS OF THE DRAWING

FIG. 1 is a section taken along the line I-I through a semiconductor device shown in FIG. 2;

FIG. 2 is illustrative of a semiconductor device in accordance with an embodiment of the present invention;

FIG. 3 is illustrative of a method of manufacturing the semiconductor device in accordance with the present invention;

FIG. 4 is further illustrative of the method of manufacturing the semiconductor device in accordance with the present invention;

FIG. 5 is still further illustrative of the method of manufacturing the semiconductor device in accordance with the present invention;

FIG. 6 is yet further illustrative of the method of manufacturing the semiconductor device in accordance with the present invention;

FIG. 7 is even further illustrative of the method of manufacturing the semiconductor device in accordance with the present invention;

FIG. 8 is a section illustrating a modification of the method of manufacturing a semiconductor device in accordance with the present invention;

FIG. 9 is a plan view illustrating the modification of the method of manufacturing a semiconductor device in accordance with the present invention;

FIG. 10 shows a circuit board on which is mounted the semiconductor device of an embodiment of the present invention;

FIG. 11 shows an electronic instrument having the semiconductor device of an embodiment of the present invention; and

FIG. 12 shows another electronic instrument having the semiconductor device of an embodiment of the present invention.

### DETAILED DESCRIPTION OF THE EMBODIMENT

An embodiment of the present invention may ensure that the thickness of the package does not increase and also make it difficult for the sealing section to peel away.

(1) A semiconductor device according to one embodiment of the present invention includes:
an interposer having a first wiring pattern formed on a first surface of the interposer, a second wiring pattern formed on a second surface of the interposer, and a penetrating-hole formed in the interposer;
a first semiconductor chip having a first electrode and being mounted on the first surface of the interposer in such a manner that the first electrode overlaps with the penetrating-hole;
a second semiconductor chip having a second electrode and being stacked on the first semiconductor chip with the second electrode facing away from the first semiconductor chip;
a first wire disposed on a side of the second surface and being bonded to the first electrode and the second wiring pattern;
a second wire disposed on a side of the first surface and being bonded to the second electrode and the first wiring pattern; and
a sealing section which includes a first portion provided on the first surface of the interposer, a second portion provided on the second surface of the interposer, and a third portion provided through the penetrating-hole and linking the first and second portions, seals the first and second semiconductor chips, seals the first and second wires, and seals the bonding portions of the first and second wires with the first and second wiring patterns.

Since this embodiment of the present invention ensures that the first and second semiconductor chips are superimposed with the first and second electrodes facing in the opposite directions, it makes it possible to bond the first wire to the first electrode without using a spacer. For that reason, the thickness of the package does not become large. Since the first and second portions of the sealing section are linked by the third portion, it is difficult for the sealing sections to peel away.

(2) This semiconductor device may further includes a plurality of the first wires being bonded to a plurality of the first electrodes, respectively, and all of the first wires may be bonded to the second wiring pattern at regions except an area in which the first semiconductor chip is located.

(3) With this semiconductor device,
the first electrode may be provided on each of two edge portions of the first semiconductor chip opposite to each other, and
the first wire may extend from one of the edge portions of the first semiconductor chip over the other edge portion and may bond to the second wiring pattern on an outer side of the first semiconductor chip.

(4) With this semiconductor device,
the first semiconductor chip may include a plurality of the first electrodes,
the second semiconductor chip may include a plurality of the second electrodes,
the first and second electrodes may be arrayed in accordance with the same array pattern, and
one of the first electrodes and one of the second electrodes disposed at overlapping positions in the stacked first and second semiconductor chips may be connected electrically.

(5) A circuit board according to another embodiment of the present invention has the above semiconductor device mounted thereon.

(6) An electronic instrument according to a further embodiment of the present invention has the above semiconductor device.

(7) A method of manufacturing a semiconductor device includes:
(a) mounting a first semiconductor chip on an interposer, the first semiconductor chip having a first electrode, and the interposer having a first wiring pattern formed on a first surface of the interposer, a second wiring pattern formed on a second surface of the interposer, and a penetrating-hole formed in the interposer, in such a manner that the first electrode overlaps with the penetrating-hole;
(b) stacking a second semiconductor chip having a second electrode on the first semiconductor chip, with the second electrode facing away from the first semiconductor chip;
(c) bonding a first wire to the first electrode and the second wiring pattern on a side of the second surface;
(d) bonding a second wire to the second electrode and the first wiring pattern on a side of the first surface; and
(e) by using a transfer molding method, sealing the first and second semiconductor chips, sealing the first and second wires, and sealing the bonding portions of the first and second wires with the first and second wiring patterns,
wherein in the step (e), resin flows through the penetrating-hole from one of the first and second surfaces of the interposer to the other, to form a sealing section which is formed integrally of a first portion on the first surface, a second portion on the second surface, and a third portion linking the first and second portions through the penetrating-hole.

Since this embodiment of the present invention superimposes the first and second semiconductor chips with the first and second electrodes facing in the opposite directions, it makes it possible to bond the first wire to the first electrode without using a spacer. For that reason, the thickness of the package does not become large. During the sealing, the resin flows from one of the first and second surfaces of the interposer to the other through the penetrating-hole, so that the first, second, and third portions of the interposer can be formed at the same time, thus making it possible to shorten or simplify the process. Since the first and second portions of the sealing section are linked by the third portion, it is difficult for the sealing sections to peel away.

Embodiments of the present invention are described below, with reference to the accompanying figures.

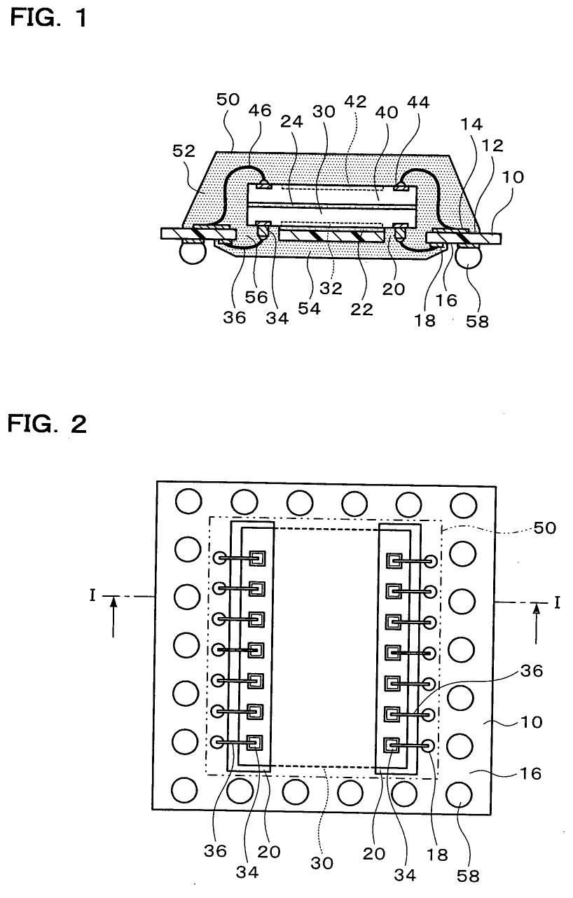

FIGS. 1 and 2 are illustrative of a semiconductor device in accordance with an embodiment of the present invention. FIG. 1 is a section taken along I-I of the semiconductor device shown in FIG. 2.

The semiconductor device has an interposer 10. The interposer 10 could be a substrate or it could be a plate. The interposer 10 could be formed to be rectangular. The interposer 10 could be formed of a resin such as a polyimide resin, or it could be formed of a material that is a mixture of an organic material such as a resin and an inorganic material, or it could be a metal substrate or a ceramic substrate. A first wiring pattern 14 is formed on a first surface 12 of the interposer 10. A second wiring pattern 18 is formed on a second surface 16 of the interposer 10. Each of the first and second wiring patterns 14 and 18 could be configured to have wiring for electrical connections at a plurality of points and lands that provide electrical connection points for other components. The first and second wiring patterns 14 and 18 could be connected together electrically by penetrating-holes (not shown in the figures), or they could be electrically independent.

One or a plurality of penetrating-holes 20 is formed in the interposer 10. Each penetrating-hole 20 links the first and second surfaces 12 and 16. The first and second wiring patterns 14 and 18 are formed in such a manner that they do not overlap with the penetrating-holes 20. The penetrating-holes 20 could be formed to have an extended shape (rectangular, elongated circular, or ellipse).

The semiconductor device has a first semiconductor chip 30. Integrated circuitry 32 is formed on the first semiconductor chip 30. The first semiconductor chip 30 has a plurality of first electrodes 34. Each first electrode 34 could consist of just a pad, but it could also consist of a pad and a bump formed thereabove, as shown in FIG. 1. The first electrodes 34 are provided on the surface on which the integrated circuitry 32 is formed. The first semiconductor chip 30 could also be formed to have a peripheral shape. In such a case, the first electrodes 34 would be provided in either one row or a plurality of rows on edge portions of the first semiconductor chip 30. The first electrodes 34 could also be disposed in one or a plurality of rows on both edge portions on mutually opposite sides of the first semiconductor chip 30. In the example shown in FIG. 2, the first electrodes 34 are arrayed along the edges of two parallel sides of a rectangular surface of the first semiconductor chip 30, but they could equally well be arrayed along the edges of all four sides of the rectangle. As a modification, the first electrodes 34 could also be provided in one or a plurality of rows in a central portion of the first semiconductor chip 30.

The first semiconductor chip 30 is mounted in the interposer 10. The first semiconductor chip 30 is attached to the interposer 10 by adhesive 22. The adhesive 22 could be a resin. The adhesive 22 could also be of type that hardens upon the application of energy (such as hardening due to heat or ultraviolet rays). The adhesive 22 could also be electrically insulating.

The surface of the first semiconductor chip 30 on which the first electrodes 34 are formed faces the first surface 12 of the interposer 10. Note that the entirety of the integrated circuitry 32 could overlap with the first surface 12 of the interposer 10, or part of the integrated circuitry 32 could overlap with the penetrating-holes 20.

The first semiconductor chip 30 is disposed in such a manner that the first electrodes 34 overlap with the penetrating-holes 20. The first electrodes 34 could also fit within the penetrating-holes 20, as shown in FIG. 1. Furthermore, the first electrodes 34 could also protrude from the second surface 16 of the interposer 10 through the penetrating-holes 20. Alternatively, the first electrodes 34 could be disposed so as not to fit within the penetrating-holes 20. The arrangement could also be such that one of the penetrating-holes 20 is overlaid by two or more of the first electrodes 34 (a plurality of the first electrodes 34, but not all of them) arrayed along one edge, as shown by way of example in FIG. 2. The first semiconductor chip 30 is disposed in such a manner that the penetrating-holes 20 are not completely covered (blocked) thereby. In other words, part of each penetrating-hole 20 is not overlain by the first semiconductor chip 30. This maintains the linked state between the first and second surfaces 12 and 16 of the interposer 10 through the penetrating-holes 20, even when the first semiconductor chip 30 is mounted thereon.

First wires 36 are bonded between the first electrodes 34 and the second wiring pattern 18 formed on the interposer 10. The first electrodes 34 and the second wiring pattern 18 are electrically connected thereby. The first wires 36 are disposed on the second surface 16 side. The first wires 36 could be disposed in such a manner that bonding portions thereof with the first electrodes 34 are positioned so as to overlap with the penetrating-holes 20 and be positioned within the penetrating-holes 20, or they could be positioned so as to protrude from the penetrating-holes 20. The first wires 36 could also be bonded to the first electrodes 34 at positions that are deeper within the thickness direction of the interposer 10 from the second surface 16 within the penetrating-holes 20. When a plurality of the first wires 36 are bonded to a plurality of the first electrodes 34, all of the first wires 36 could be bonded to the second wiring pattern 18 at positions that avoid the area that overlaps with the first semiconductor chip 30.

The semiconductor device also has a second semiconductor chip 40. Integrated circuitry 42 is formed on the second semiconductor chip 40. The second semiconductor chip 40 has a plurality of second electrodes 44. Each of the second electrodes 44 could consist of just a pad, but it could also consist of a pad and a bump formed thereabove. Further details of the second semiconductor chip 40 could be similar to the details of the first semiconductor chip 30. The plurality of first electrodes 34 and the plurality of second electrodes 44 could be arrayed in the same pattern. The first and second semiconductor chips 30 and 40 could have the same size, the same shape, and the same configuration. Note that “the same” in this context means at least the same from the design point of view, ignoring differences due to errors in manufacture. Alternatively, the second semiconductor chip 40 could be larger than the first semiconductor chip 30.

The second semiconductor chip 40 is placed on top of the first semiconductor chip 30. The second electrodes 44 (or the surface on which they are formed) faces in the opposite direction to the first electrodes 34 (or the surface on which they are formed). One of the first electrodes 34 could overlap with one of the second electrodes 44. The first and second semiconductor chips 30 and 40 could be fastened together by adhesive 24.

Second wires 46 are bonded between the second electrodes 44 and the first wiring pattern 14 formed on the interposer 10. The second electrodes 44 and the first wiring pattern 14 are electrically connected thereby. The second wires 46 are disposed on the first surface 12 side. When a plurality of the second wires 46 are bonded to a plurality of the first electrodes, all of the second wires 46 could be bonded to the first wiring pattern 14 at positions that avoid the area that overlaps with the second semiconductor chip 40.

The semiconductor device has a sealing section 50. The sealing section 50 has a first portion 52 provided on the first surface 12 of the interposer 10. The sealing section 50 has a second portion 54 provided on the second surface 16 of the interposer 10. The sealing section 50 (such as the first portion 52 thereof) seals in the first and second semiconductor chips 30 and 40. The sealing section 50 (such as the first portion 52 thereof) seals in the second wires 46. The sealing section 50 (such as the second portion 54 thereof) seals in the first wires 36. The sealing section 50 (such as the first portion 52 thereof) seals in the bonding portions between the first wiring pattern 14 and the second wires 46. The sealing section 50 (such as the second portion 54 thereof) seals in the bonding portions between the second wiring pattern 18 and the first wires 36. The sealing section 50 has a third portion 56 provided so as to communicate within each of the penetrating-holes 20 and link together the first portion 52 and the second portion 54. The sealing section 50 (such as the third portion 56) could also seal the first electrodes 34 of the first semiconductor chip 30.

The sealing section 50 could be formed of a resin (such as molded resin). The sealing section 50 could have a coefficient of thermal expansion that is less than that of the interposer 10. To ensure that the coefficient of thermal expansion is smaller, the sealing section 50 could also be formed to comprise silica. In this embodiment of the present invention, the first and second portions 52 and 54 of the sealing section 50 are connected by the third portion 56, making it difficult for the sealing section 50 to peel away.

The semiconductor device could also have a plurality of external terminals (such as solder balls) 58. The external terminals 58 are provided on the second surface 16 side of the interposer 10 (more specifically, on the second wiring pattern 18, such as on lands thereof). The external terminals 58 could be formed of either a soft solder or a hard solder. A solder that does not comprise lead (hereinafter called a lead-free solder) could be used as the solder material. A tin-silver (Sn—Ag), tin-bismuth (Sn—Bi), tin-zinc (Sn—Zn), or tin-copper (Sn—Cu) alloy could be used as the lead-free solder, and at least one of silver, bismuth, zinc, and copper could be added to that alloy.

Since this embodiment of the invention superimposes the first and second semiconductor chips 30 and 40 with the first and second electrodes 34 and 44 facing in opposite directions, the first wires 36 can be bonded to the first electrodes 34 without using spacers. For that reason, the thickness of the package does not become large.

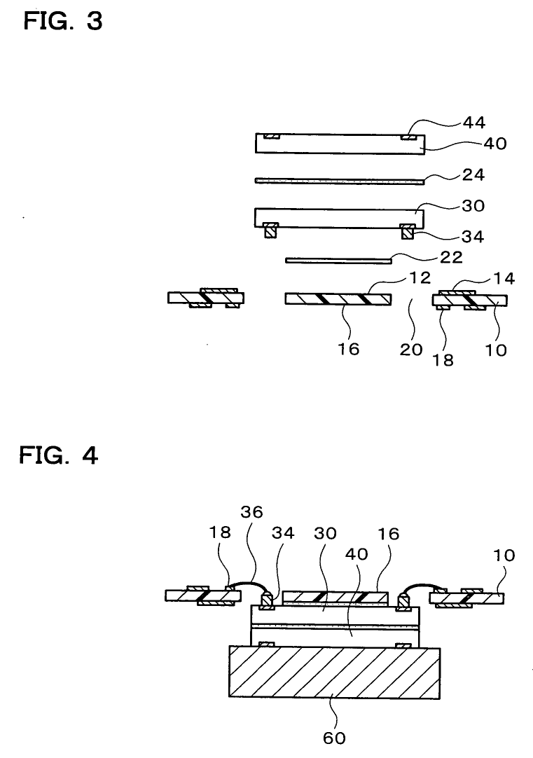

FIG. 3 to FIG. 7 are illustrative of a method of manufacturing the semiconductor device in accordance with the present invention. As shown in FIG. 3, the first semiconductor chip 30 is mounted on the interposer 10 in such a manner that the first electrodes 34 overlap with the penetrating-holes 20. The interposer 10 and the first semiconductor chip 30 could be fastened together by the adhesive 22. The second semiconductor chip 40 is then placed upon the first semiconductor chip 30 with the second electrodes 44 facing away from the first semiconductor chip 30. The first and second semiconductor chips 30 and 40 could be fastened together by the adhesive 24. The positional relationships between the interposer 10 and the first and second semiconductor chips 30 and 40 correspond to the details derived from the description of the semiconductor device above.

As shown in FIG. 4, the first wires 36 are bonded to the first electrodes 34 and the second wiring pattern 18 on the second surface 16 side of the interposer 10. The first and second semiconductor chips 30 and 40 could be placed upon a block 60 with the first electrodes 34 upward, for this bonding. The second semiconductor chip 40 could be placed in contact with the block 60. The block 60 could also be a heater block. In such a case, the first and second semiconductor chips 30 and 40 can be heated thereby, and also the first electrodes 34 can be heated.

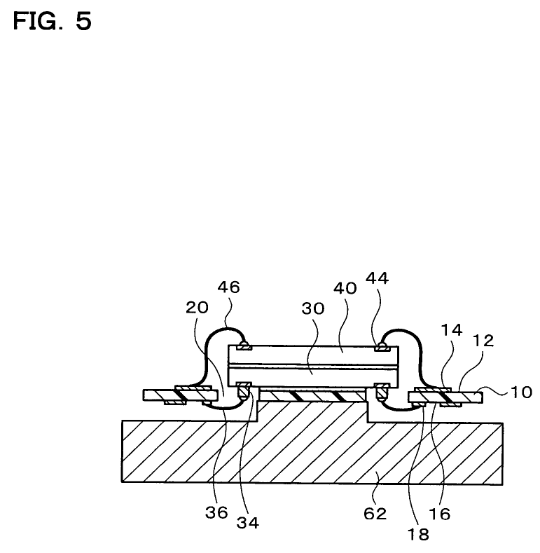

As shown in FIG. 5, the second wires 46 are bonded to the second electrodes 44 and the first wiring pattern 14 on the first surface 12 side of the interposer 10. The first and second semiconductor chips 30 and 40 could be placed upon a block 62 with the second electrodes 44 upward, for this bonding. The interposer 10 could be placed in contact with the block 62. The block 62 could also be a heater block. In such a case, the first and second semiconductor chips 30 and 40 can be heated thereby, and also the second electrodes 44 can be heated. If the first wires 36 have been provided previously, the block 62 is formed to avoid them. If the portions of the first wires 36 that are bonded to the first electrodes 34 are at positions deeper within the penetrating-holes 20 in the thickness direction of the interposer 10, the loops of the first wires 36 can be made shallower with respect to the second surface 16. In such a case, a depression, hollow, or cutout in the block 62 used to avoid the first wires 36 can be made smaller. The steps of FIGS. 4 and 5 can be performed in either order.

As an example that differs from that shown in FIGS. 4 and 5, the first or second electrodes 34 or 44 that are bonded second could be provided at positions that are closer to the center of the first or second semiconductor chip 30 or 40 than the electrodes that are bonded first. In such a case, the latter bonding can be done on (directly above) the block 60 or 62 that is formed to avoid the first or second wires 36 or 46 that were bonded first. In other words, since the portions at which the first or second wires 36 or 46 that are bonded later are supported by the block 60 or 62, breakage of the first or second semiconductor chip 30 or 40 can be prevented.

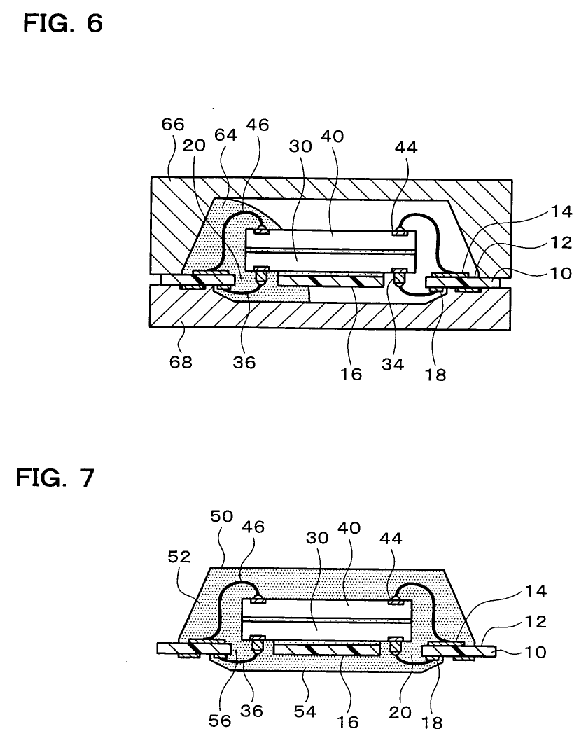

As shown in FIG. 6, the first and second semiconductor chips 30 and 40 are sealed by resin 64. The first and second wires 36 and 46 are also sealed by the resin 64. The bonding portions of the first and second wires 36 and 46 with the first and second wiring patterns 14 and 18 are sealed by the resin 64. The bonding portions of the first and second wires 36 and 46 with the first and second electrodes 34 and 44 are sealed by the resin 64.

A transfer molding method could be employed in the sealing process, or an upper mold 66 and a lower mold 68 could be used therefore. For example, the resin 64 could flow through the penetrating-holes 20 from one of the first and second surfaces 12 and 16 of the interposer 10 to the other.

Thus the sealing section 50 is formed integrally to have the first portion 52 on the first surface 12, the second portion 54 on the second surface 16, and the third portion 56 linking the first and second portions 52 and 54 through the penetrating-holes 20, as shown in FIG. 7.

In this embodiment of the invention, the semiconductor circuit can be manufactured by the above steps. This process comprises details that can be deduced from the description of the manufacture of the semiconductor device. Since the resin 64 flows from one of the first and second surfaces 12 and 16 of the interposer 10 to the other through the penetrating-holes 20 during the sealing process, this embodiment makes it possible to form the first, second, and third portions 50, 52, and 54 of the sealing section 50 at the same time, thus making it possible to shorten or simplify the process. Since the first and second portions 52 and 54 are linked by the third portion 56, it is difficult for the sealing section 50 to peel away from the interposer 10.

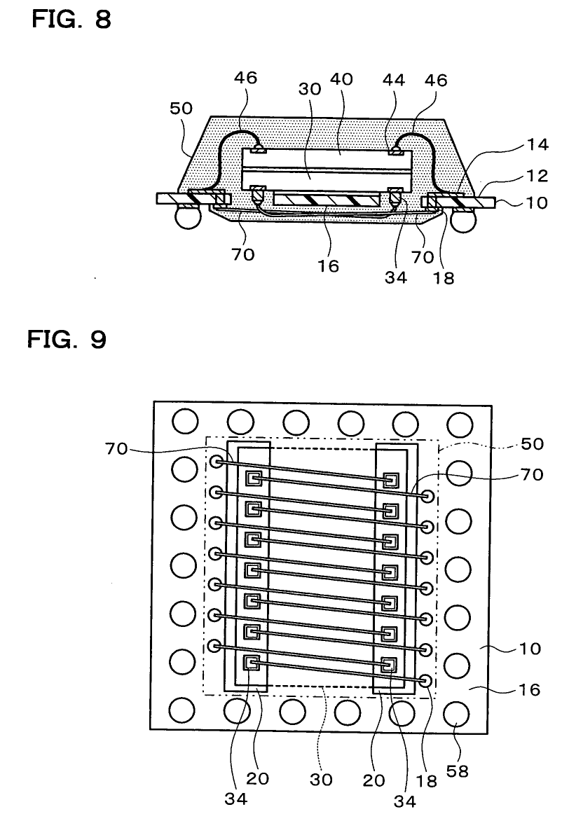

A section through a modification of the above-described embodiment is shown in FIG. 8 with a plan view thereof being shown in FIG. 9. The first semiconductor chip 30 is provided with the first electrodes 34 on both edges of mutually opposite sides. The first semiconductor chip 30 comprises a plurality of the first electrodes 34. The second semiconductor chip 40 comprises a plurality of the second electrodes 44. The first and second electrodes 34 and 44 are each arrayed in accordance with the same pattern.

This modification differs from the above described embodiment in the provision of first wires 70. As shown in FIG. 9, the first wires 70 extend from one of the two edges of the first semiconductor chip 30 over the other edge thereof. The first wires 70 are then bonded to the second wiring pattern 18 on the outer side of the first semiconductor chip 30. This configuration ensures that the bonding portions of the first and second wiring patterns 14 and 18 with the first and second electrodes 34 and 44 are close at the same positions in the array pattern, even when the first and second semiconductor chips 30 and 40 are disposed back-to-back, as shown in FIG. 8. The first and second electrodes 34 and 44 at overlapping positions of the superimposed first and second semiconductor chips 30 and 40 can also be connected electrically. Specifically, the first and second wires 70 and 46 that have been bonded to the first and second electrodes 34 and 44 at overlying positions are bonded to the first and second wiring patterns 14 and 18, respectively, and the bonding portions of these the first and second wires 70 and 46 with the first and second wiring patterns 14 and 18 are connected electrically by penetrating-holes or the like (not shown in the figures).

This modification enables electrical connections of the first and second electrodes 34 and 44 at the same positions of the array pattern, even when two semiconductor chips have electrodes that are arrayed in a mutually symmetrical relationship (i.e., mirror chips). Further details of this example can be obtained from the above description of the embodiment of the present invention.

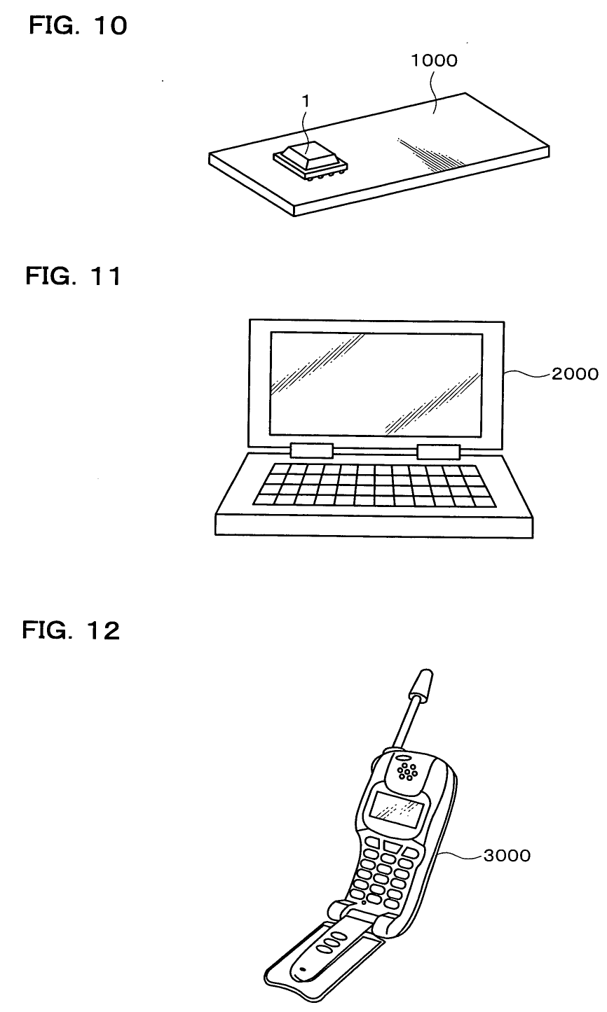

A circuit board 1000 on which is mounted a semiconductor device 1 in accordance with the above-described embodiment is shown in FIG. 10. A notebook personal computer 2000 shown in FIG. 11 and a portable phone 3000 shown in FIG. 12 are examples of electronic instruments having this semiconductor device.

Although only some embodiments of the present invention have been described in detail above, those skilled in the art will readily appreciate that many modifications are possible in the embodiments without materially departing from the novel teachings and advantages of this invention. Accordingly, all such modifications are intended to be included within scope of this invention.

1. A semiconductor device comprising:
an interposer having a first wiring pattern formed on a first surface of the interposer, a second wiring pattern formed on a second surface of the interposer, and a penetrating-hole formed in the interposer;
a first semiconductor chip having a first electrode and being mounted on the first surface of the interposer in such a manner that the first electrode overlaps with the penetrating-hole;
a second semiconductor chip having a second electrode and being stacked on the first semiconductor chip with the second electrode facing away from the first semiconductor chip;
a first wire disposed on a side of the second surface and being bonded to the first electrode and the second wiring pattern;
a second wire disposed on a side of the first surface and being bonded to the second electrode and the first wiring pattern; and
a sealing section which includes a first portion provided on the first surface of the interposer, a second portion provided on the second surface of the interposer, and a third portion provided through the penetrating-hole and linking the first and second portions, seals the first and second semiconductor chips, seals the first and second wires, and seals the bonding portions of the first and second wires with the first and second wiring patterns.

2. The semiconductor device as defined by claim 1, further comprising a plurality of the first wires being bonded to a plurality of the first electrodes, respectively,
wherein all of the first wires are bonded to the second wiring pattern at regions except an area in which the first semiconductor chip is located.

3. The semiconductor device as defined by claim 1,
wherein the first electrode is provided on each of two edge portions of the first semiconductor chip opposite to each other, and
wherein the first wire extends from one of the edge portions of the first semiconductor chip over the other edge portion and bonds to the second wiring pattern on an outer side of the first semiconductor chip.

4. The semiconductor device as defined by claim 3,
wherein the first semiconductor chip includes a plurality of the first electrodes,
wherein the second semiconductor chip includes a plurality of the second electrodes,
wherein the first and second electrodes are arrayed in accordance with the same array pattern, and
wherein one of the first electrodes and one of the second electrodes disposed at overlapping positions in the stacked first and second semiconductor chips are connected electrically.

5. A circuit board on which is mounted the semiconductor device defined by claim 1.

6. A circuit board on which is mounted the semiconductor device defined by claim 2.

7. A circuit board on which is mounted the semiconductor device defined by claim 3.

8. A circuit board on which is mounted the semiconductor device defined by claim 4.

9. An electronic instrument having the semiconductor device defined by claim 1.

10. An electronic instrument having the semiconductor device defined by claim 2.

11. An electronic instrument having the semiconductor device defined by claim 3.

12. An electronic instrument having the semiconductor device defined by claim 4.

13. A method of manufacturing a semiconductor device comprising:
(a) mounting a first semiconductor chip on an interposer, the first semiconductor chip having a first electrode, and the interposer having a first wiring pattern formed on a first surface of the interposer, a second wiring pattern formed on a second surface of the interposer, and a penetrating-hole formed in the interposer, in such a manner that the first electrode overlaps with the penetrating-hole;
(b) stacking a second semiconductor chip having a second electrode on the first semiconductor chip, with the second electrode facing away from the first semiconductor chip;
(c) bonding a first wire to the first electrode and the second wiring pattern on a side of the second surface;
(d) bonding a second wire to the second electrode and the first wiring pattern on a side of the first surface; and
(e) by using a transfer molding method, sealing the first and second semiconductor chips, sealing the first and second wires, and sealing the bonding portions of the first and second wires with the first and second wiring patterns,
wherein in the step (e), resin flows through the penetrating-hole from one of the first and second surfaces of the interposer to the other, to form a sealing section which is formed integrally of a first portion on the first surface, a second portion on the second surface, and a third portion linking the first and second portions through the penetrating-hole.
